(19) United States
(12) Patent Application Publication
(10) Pub. No.: US 2025/0323168 A1
(43) Pub. Date: Oct. 16, 2025

(54) INTEGRATED CIRCUIT PACKAGE AND METHOD OF FORMING SAME

(71) Applicant: Taiwan Semiconductor Manufacturing Co., Ltd., Hsinchu (TW)

(72) Inventors: Monsen Liu, Hsinchu (TW); Shuo-Mao Chen, New Taipei City (TW); Hsien-Wei Chen, Hsinchu (TW); Shin-Puu Jeng, Hsinchu (TW)

(21) Appl. No.: 19/247,882

(22) Filed: Jun. 24, 2025

Related U.S. Application Data
(63) Continuation of application No. 18/506,739, filed on Nov. 10, 2023.
(60) Provisional application No. 63/581,039, filed on Sep. 7, 2023.

(51) Int. Cl. H01L 23/538; H01L 21/48; H01L 23/28; H01L 25/00; H01L 25/065; H10B 80/00

(52) U.S. Cl. CPC H01L 23/5383; H01L 21/4857; H01L 21/486; H01L 23/28; H01L 23/5384; H01L 25/0652; H01L 25/50; H10B 80/00

(57) ABSTRACT

A method includes forming first conductive elements on and extending through a first composite layer; forming a first polymer layer on the first composite layer; forming a first metallization pattern extending through the first polymer layer; forming a second polymer layer over the first polymer layer, wherein the second polymer layer is thinner than the first polymer layer; forming a second metallization pattern on and extending through the second polymer layer, wherein the second metallization pattern is thinner than the first metallization pattern; forming a second composite layer on the first composite layer; and forming second conductive elements extending through the second composite layer.

### PRIORITY CLAIM AND CROSS-REFERENCE

This application is a continuation of U.S. patent application Ser. No. 18/506,739, filed on Nov. 10, 2023, which claims the benefit of U.S. Provisional Application No. 63/581,039, filed on Sep. 7, 2023, each application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, and 4 illustrate cross-sectional views of intermediate steps during a process for forming an integrated circuit package, in accordance with some embodiments.

FIGS. 5, 6, 7, 8, 9, and 10 illustrate cross-sectional views of intermediate steps during a process for forming a redistribution structure of an integrated circuit package, in accordance with some embodiments.

FIGS. 11, 12, 13, 14, and 15 illustrate cross-sectional views of intermediate steps during a process for forming a redistribution structure of an integrated circuit package, in accordance with some embodiments.

FIGS. 16, 17, 18, 19, 20, 21, 22, 23, 24, 25, and 26 illustrate cross-sectional views of intermediate steps during a process for forming an integrated circuit package, in accordance with some embodiments.

FIG. 27 illustrates a cross-sectional view of a singulation process for forming an integrated circuit package, in accordance with some embodiments.

FIG. 28 illustrates a cross-sectional view of an integrated circuit package, in accordance with some embodiments.

FIG. 29 illustrates a cross-sectional view of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to embodiments in a specific context, namely integrated circuit packages and methods of forming the same. In various embodiments presented herein, a package includes a routing structure formed of multiple redistribution structures, which may be formed of polymer layers, for example. The routing structure is formed over a composite interconnect structure formed of multiple composite layers, which may be formed of prepreg layers, for example. Each redistribution structure of the routing structure has different thicknesses and conductive features of different sizes. The redistribution structures are formed using photolithographic techniques, which can improve yield and through-put of manufacturing a package. The use of multiple composite layers can allow for improved structural stability and thermal performance of a package.

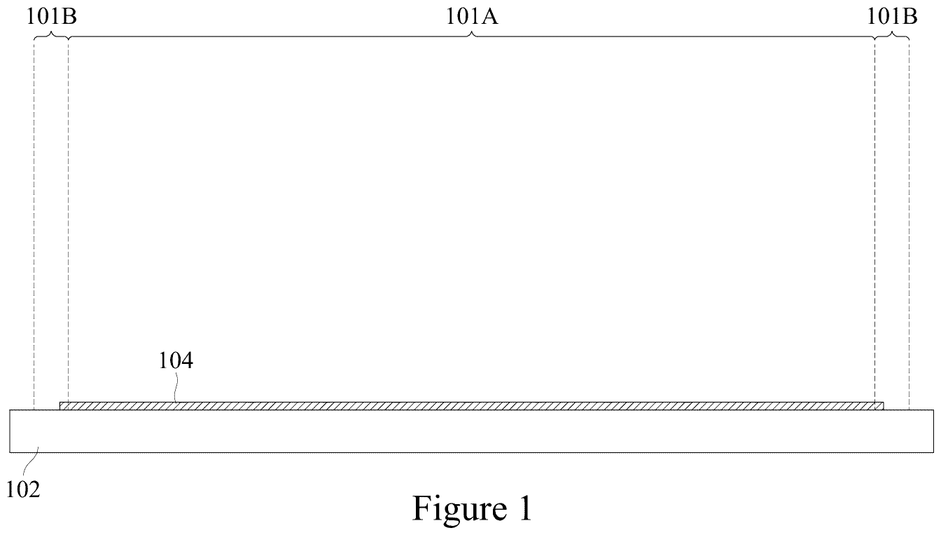

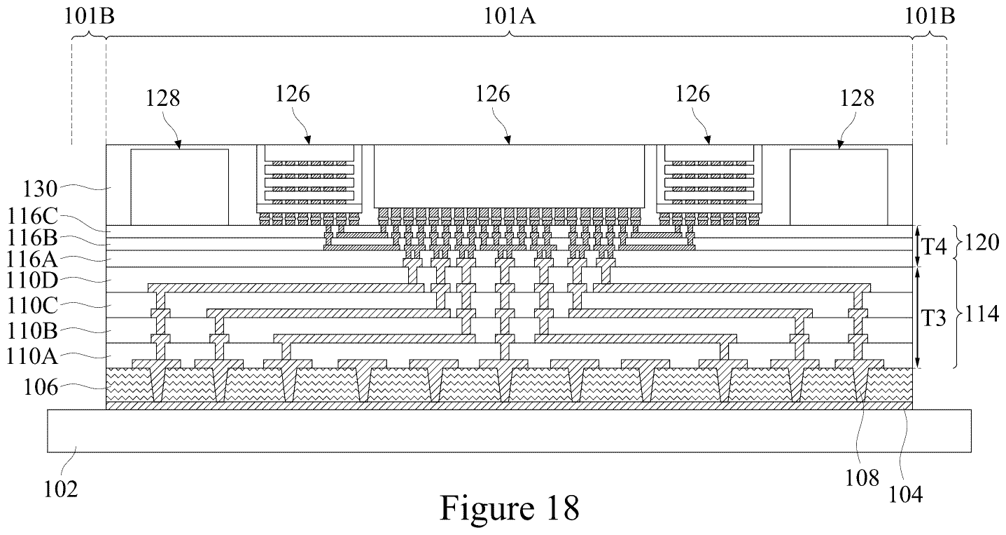

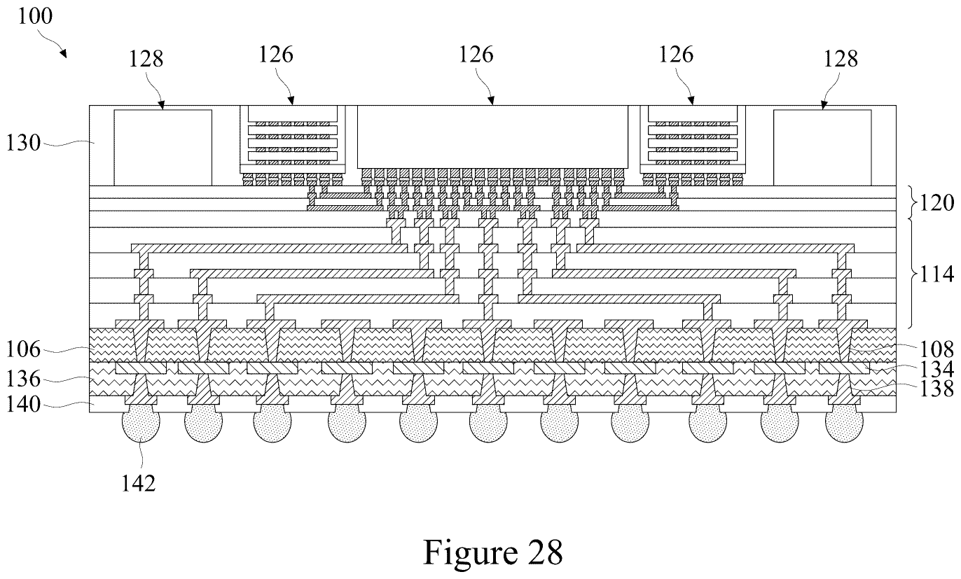

FIGS. 1 through 28 illustrate cross-sectional views of intermediate steps in the formation of an integrated circuit package 100 (see FIG. 28), in accordance with some embodiments. In FIG. 1, a carrier substrate 102 is provided or formed. In some embodiments, the carrier substrate 102 comprises a semiconductor material (such as silicon, or the like), a dielectric material (such as glass, a ceramic material, quartz, plastic, or the like), a combination thereof, or the like. The carrier substrate 102 may be a wafer, such that multiple package components can be formed on the carrier substrate 102 simultaneously. FIGS. 1-18 illustrate intermediate steps in the formation of a single package component in a structure region 101A of the carrier substrate 102 that is surrounded by an edge region 101B. In some embodiments, the edge regions 101B may be trimmed, described below for FIG. 18. It should be understood that multiple package components may be formed in the structure region 101A and subsequently processed to form multiple integrated circuit packages 100. The multiple integrated circuit packages 100 may be singulated to form individual integrated circuit packages 100, described in greater detail below.

Further in FIG. 1, a seed layer 104 is formed over the carrier substrate 102, in accordance with some embodiments. The seed layer 104 may comprise a metal layer, which may be a single layer or a composite layer comprising multiple sub-layers formed of different materials. In a particular embodiment, the seed layer 104 comprises a titanium layer and a copper layer over the titanium layer. The seed layer 104 may be formed using, for example, physical vapor deposition (PVD), sputtering, or the like. Other materials or deposition techniques are possible.

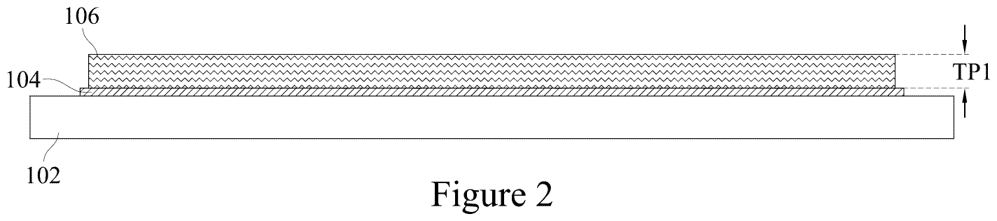

In FIG. 2, a first composite layer 106 is formed over the seed layer 104, in accordance with some embodiments. The first composite layer 106 is an insulating layer formed of one layer of composite material or multiple layers of composite material(s). In some embodiments, the first composite layer 106 may be formed from a pre-impregnated composite fiber (“prepreg”) material or the like, though other materials are possible. For example, the first composite layer 106 may be formed from a prepreg material comprising glass fibers pre-impregnated with resin, such as an epoxy-impregnated glass-cloth laminate, a polyimide-impregnated glass-cloth laminate, or the like. The first composite layer 106 may comprise a glass cloth having any suitable weight, thickness, weave, density, resin content, coefficient of thermal expansion (CTE), or the like. In some cases, the materials of the first composite layer 106 may be chosen such that the first composite layer 106 has a CTE that is similar to the CTE of other features of the package such as integrated circuit dies, a support ring, other composite layers, or the like. The first composite layer 106 may comprise a single prepreg material or a stack of prepreg materials. In some embodiments, the first composite layer 106 may be formed on the seed layer 104 using a suitable process such as a lamination process or the like. In some embodiments, the first composite layer 106 may have a thickness TP1 that is in the range of about 100 μm to about 300 μm, though other thicknesses are possible. In some cases, forming an insulating layer from a composite material such as prepreg can allow for packages to be formed having improved structural strength and a smaller overall thickness.

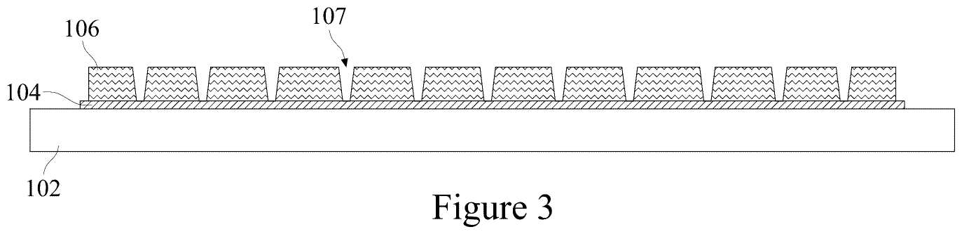

In FIG. 3, openings 107 are formed in the first composite layer 106, in accordance with some embodiments. The openings 107 may extend through the first composite layer 106 to expose portions of the seed layer 104. The openings 107 may be formed using a mechanical drilling process, a laser drilling process, a photolithographic masking and etching process, or another suitable process. In some embodiments, each opening 107 may have a width in the range of about 100 μm to about 300 μm, though other widths are possible.

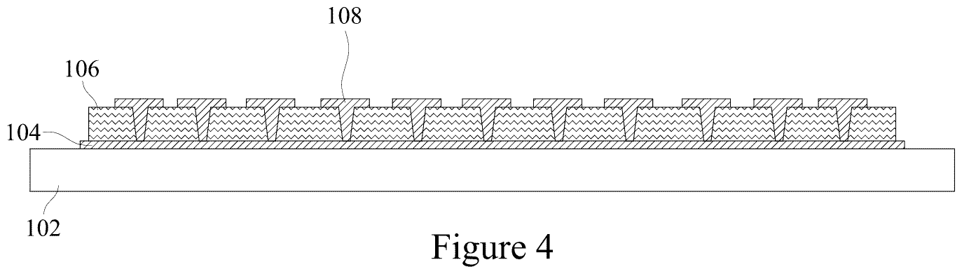

In FIG. 4, conductive material is deposited to form a metallization pattern 108, in accordance with some embodiments. The metallization pattern 108 includes conductive via portions that extend through the first composite layer 106 and physically and electrically contact the underlying seed layer 104. As shown in FIG. 4, the metallization pattern 108 may also include conductive element portions that extend along the top surface of the first composite layer 106, such as conductive lines, conductive pads, or the like. In some embodiments, the conductive element portions of the metallization pattern 108 on the top surface of the first composite layer 106 may have a thickness in the range of about 20 μm to about 40 μm, though other thicknesses are possible. In some cases, the metallization pattern 108 and the first composite layer 106 together may be considered an “interconnect layer.”

The metallization pattern 108 may comprise a conductive material such as copper, tungsten, aluminum, silver, gold, ruthenium, cobalt, a combination thereof, or the like. The conductive material may be deposited using a suitable technique, such as plating (e.g., electroplating or electroless plating), chemical vapor deposition (CVD), physical vapor deposition (PVD), atomic layer deposition (ALD), sputtering, or another technique. Other materials or deposition techniques are possible. In some embodiments, the metallization pattern 108 may include an optional barrier layer, liner layer, or the like (not shown) that is covered by the conductive material.

In some embodiments, the metallization pattern 108 may be formed by depositing a blanket layer of the conductive material that fills the openings 107 and covers the top surface of the first composite layer 106, and then patterning the blanket layer. The conductive material may be patterned using suitable photolithographic masking and etching techniques. For example, a photoresist (not shown) may be formed and patterned on the conductive material. The photoresist may be formed by spin coating or the like and may be exposed to light for patterning. The patterned photoresist may cover portions of the conductive material corresponding to the metallization pattern 108 while exposing other portions of the conductive material. An etching process may then be performed to remove the exposed portions of the conductive material, with the metallization pattern 108 formed by the remaining portions of the conductive material. The etching process may include a wet etching process and/or a dry etching process. The photoresist may then be removed using a suitable process, such as an ashing or stripping process.

In some embodiments, the metallization pattern 108 may be formed by first forming a patterned photoresist on the first composite layer 106. For example, a photoresist (not shown) may be formed by spin coating or the like and may be exposed to light for patterning. The patterned photoresist may expose portions of the first composite layer 106 corresponding to the metallization pattern 108, such as exposing the openings 107. The conductive material may then be deposited using a suitable technique. The photoresist and overlying portions of the conductive material can be removed using a suitable technique, with the remaining portions of the conductive material forming the metallization pattern 108.

In some embodiments, the metallization pattern 108 may be formed by first forming a seed layer (not shown) over the first composite layer 106 and in the openings 107. A photoresist is then formed and patterned on the seed layer. The photoresist may be formed by spin coating or the like and may be exposed to light for patterning. The pattern of the photoresist corresponds to the metallization pattern 108. The patterning forms openings through the photoresist to expose the seed layer. A conductive material is then formed in the openings of the photoresist and on the exposed portions of the seed layer. The conductive material may be formed by plating, such as electroplating or electroless plating, or the like. The photoresist and portions of the seed layer on which the conductive material is not formed are removed. Once the photoresist is removed, exposed portions of the seed layer are removed, such as by using an acceptable etching process, such as a wet etching process and/or a dry etching process. The remaining conductive material and underlying portions of the seed layer form the metallization pattern 108. These are examples, and other formation techniques are possible.

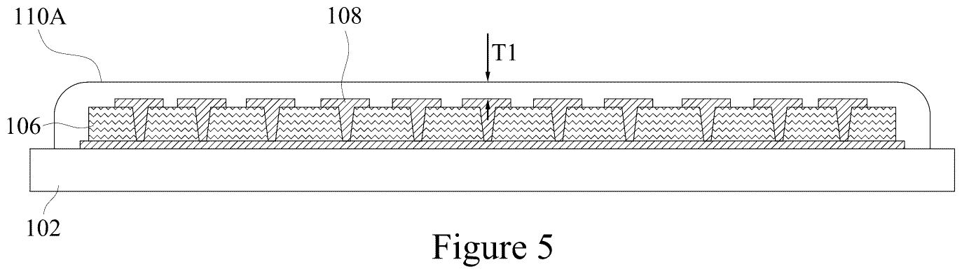

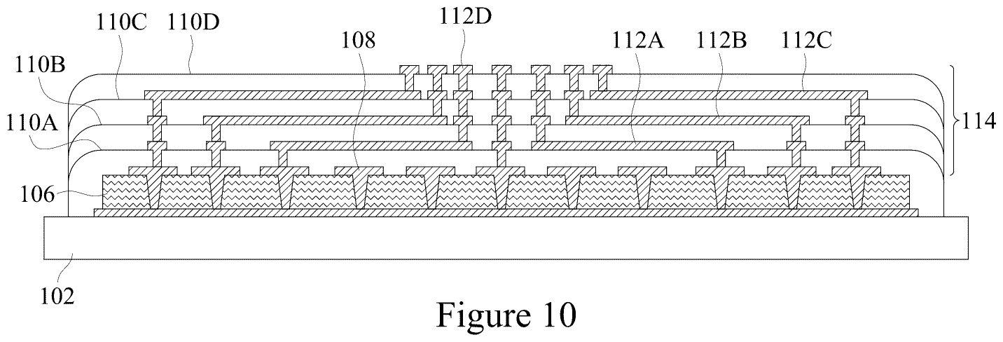

FIGS. 5 through 10 illustrate the formation of a first redistribution structure 114 (see FIG. 10), in accordance with some embodiments. The first redistribution structure 114 comprises a plurality of metallization patterns 112A-D formed in a plurality of dielectric layers 110A-D. The metallization patterns 112A-D may include conductive lines, conductive vias, conductive pads, or other conductive features, and may be considered redistribution layers or interconnects in some cases. The first redistribution structure 114 described herein is an example, and may have a different numbers, arrangements, or configurations of dielectric layers or metallization patterns in other embodiments. For example, if fewer dielectric layers and metallization patterns are to be formed, some steps and processes discussed below may be omitted. If more dielectric layers and metallization patterns are to be formed, some steps and processes discussed below may be repeated.

In FIG. 5, a dielectric layer 110A is deposited over the first composite layer 106 and the metallization pattern 108, in accordance with some embodiments. In some embodiments, the dielectric layer 110A is formed of a polymer, which may be a photo-sensitive material such as polybenzoxazole (PBO), polyimide, benzocyclobutene (BCB), or the like, that may be patterned using a lithography mask. In other embodiments, the dielectric layer 110A is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 110A may be formed by any acceptable deposition process, such as spin coating, CVD, laminating, the like, or a combination thereof. In some embodiments, the dielectric layer 110A may be formed having a thickness T1 over the first composite layer 106 that is in the range of about 10 μm to about 60 μm, though other thicknesses are possible.

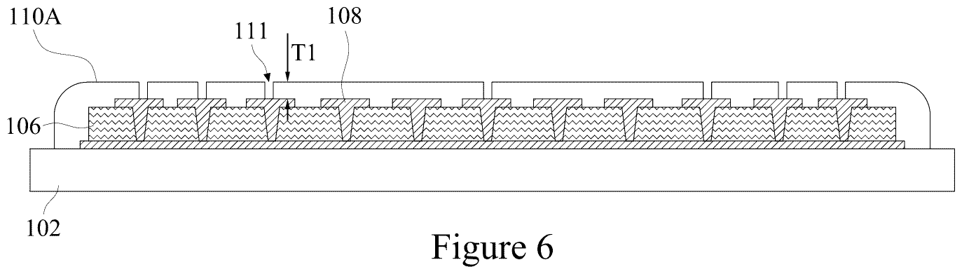

In FIG. 6, the dielectric layer 110A is patterned to form openings 111 exposing portions of the metallization pattern 108. The dielectric layer 110A may be patterned using an acceptable photolithographic process. For example, in embodiments for which the dielectric layer 110A is a photo-sensitive material, the dielectric layer 110A may be exposed to light using a lithography mask. The dielectric layer 110 A may then be developed after the exposure to form the openings 111. In other embodiments, a photoresist may be formed and patterned over the dielectric layer 110A, and then the dielectric layer 110A may be etched using the patterned photoresist as an etching mask. In some embodiments, the openings 111 may have a width in the range of about 10 μm to about 60 μm, though other widths are possible.

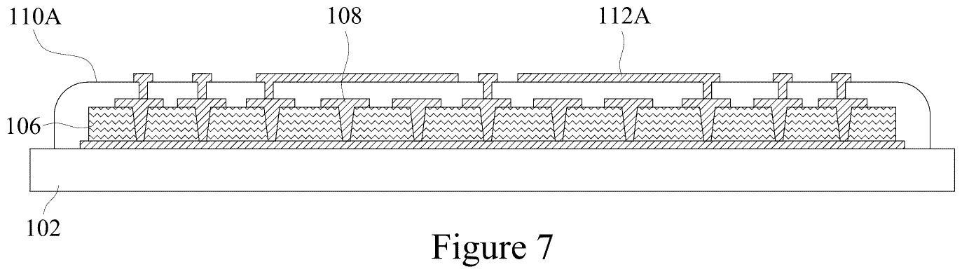

In FIG. 7, a metallization pattern 112A is formed on the dielectric layer 110A. The metallization pattern 112A comprises conductive lines that extend along the top surface of the dielectric layer 110A and conductive vias that extend through the openings 111 in the dielectric layer 110A to physically and electrically contact the metallization pattern 108. As an example of forming the metallization pattern 112A, a seed layer is first formed over the dielectric layer 110A and within the openings 111. In some embodiments, the seed layer is similar to the seed layer 104 or other seed layers described herein. For example, the seed layer may comprise a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist (not shown) is then formed and patterned on the seed layer. The photoresist may be formed by spin coating or the like and may be exposed to light for patterning. The pattern of the photoresist corresponds to the metallization pattern 112A. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed, for example, using a suitable ashing or stripping process. Once the photoresist is removed, exposed portions of the seed layer are removed using, for example, an acceptable wet etching process or dry etching process. The remaining portions of the seed layer and conductive material form the metallization pattern 112A. In some embodiments, the conductive line portions of the metallization pattern 112A have a thickness over the top surface of the dielectric layer 110A that is in the range of about 5 μm to about 30 μm, though other thicknesses are possible.

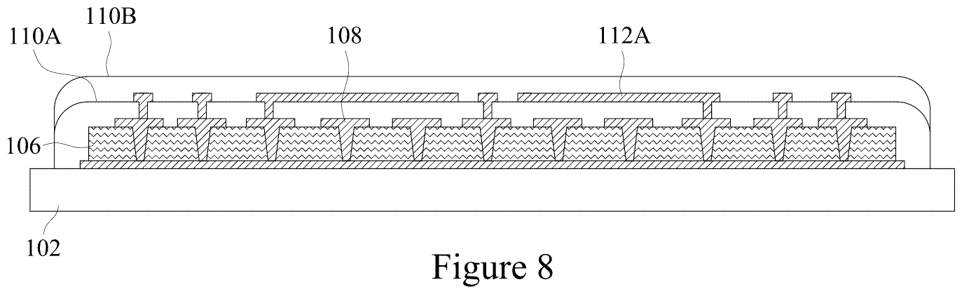

Another metallization pattern 112B may be formed over the metallization pattern 112A, in some embodiments. For example, in FIG. 8, a dielectric layer 110B may be deposited over the dielectric layer 110A and the metallization pattern 112A. The dielectric layer 110B may be a material similar to that of the dielectric layer 110A, and may be formed using similar techniques. The dielectric layer 110B may also be formed having a similar thickness (e.g., thickness T1) as the dielectric layer 110A, in some embodiments. However, in other embodiments, the dielectric layer 110B may be formed of a different material than the dielectric layer 110A and/or may have a different thickness than the dielectric layer 110A.

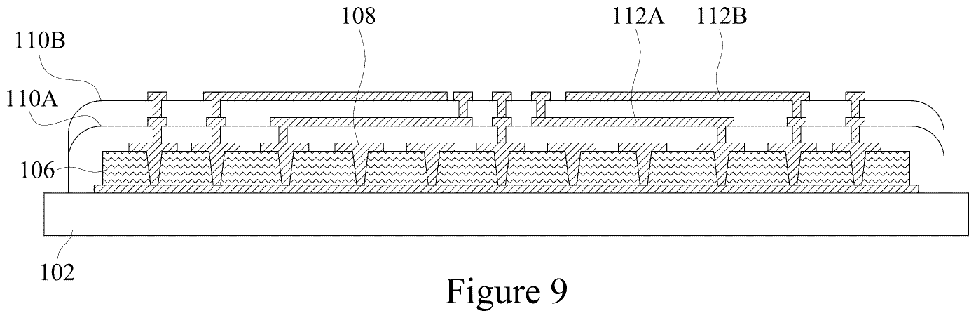

In FIG. 9, the metallization pattern 112B may be formed over the dielectric layer 110B using techniques similar to those described for the metallization pattern 112A. For example, openings may be patterned in the dielectric layer 110B that expose portions of the metallization pattern 112A. A seed layer may be formed over the dielectric layer 110B and into the openings, and a patterned photoresist may then be formed over the seed layer. A conductive material may be deposited on exposed portions of the seed layer. The conductive material may be similar to those described previously for the metallization pattern 112A. The photoresist and underlying seed layer may then be removed using suitable processes, with the remaining portions of the seed layer and conductive material forming the metallization pattern 112B. In this manner, the metallization pattern 112B comprises conductive lines that extend along the top surface of the dielectric layer 110B and conductive vias that extend through the dielectric layer 110B to physically and electrically contact the metallization pattern 112A. The conductive line portions of the metallization pattern 112B may have a thickness similar to that of the metallization pattern 112A, though the metallization patterns 112A and 112B may have different thicknesses in some embodiments.

Additional metallization patterns may be formed using techniques similar to those described in FIGS. 5-9 to form the first redistribution structure 114, in accordance with some embodiments, FIG. 10 illustrates the first redistribution structure 114 as having a four dielectric layers 110A-D and four metallization patterns 112A-D, but the first redistribution structure 114 may have any appropriate number of dielectric layers and metallization patterns. The dielectric layers of the first redistribution structure 114 may have a thickness similar to the thickness T1 described for the dielectric layer 110A, or the dielectric layers may have different thicknesses. The metallization patterns of the first redistribution structure 114 may have a thickness similar to the thickness described for the metallization pattern 112A, or the metallization patterns may have different thicknesses.

If more dielectric layers and metallization patterns are to be formed, steps and processes discussed above may be repeated. The metallization patterns may include one or more conductive elements. The conductive elements may be formed during the formation of the metallization pattern by forming the seed layer and conductive material of the metallization pattern over a surface of the underlying dielectric layer and in openings of the underlying dielectric layer, thereby interconnecting and electrically coupling various conductive lines.

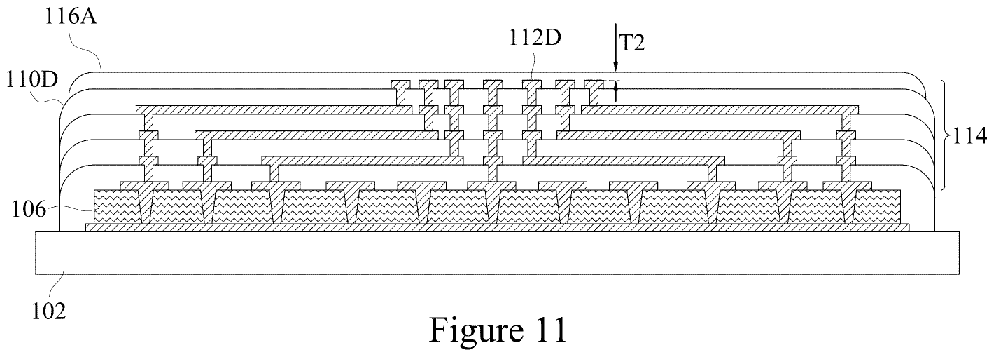

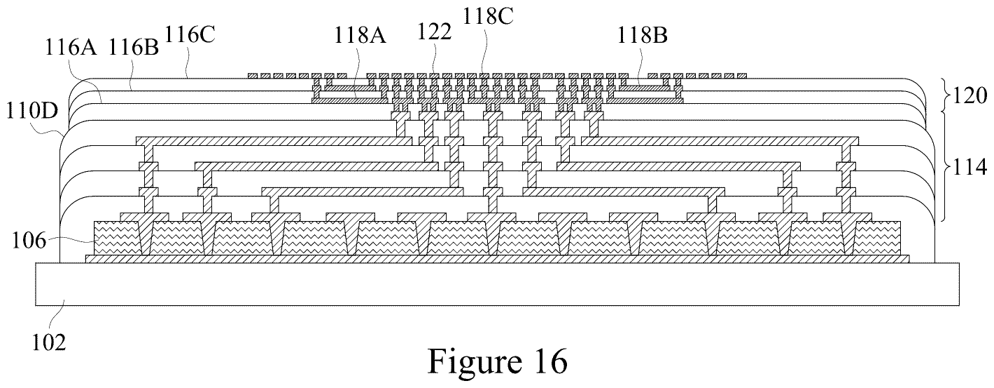

FIGS. 11 through 16 illustrate the formation of a second redistribution structure 120 (see FIG. 16) over the first redistribution structure 114, in accordance with some embodiments. The second redistribution structure 120 comprises a plurality of metallization patterns 118A-C formed in a plurality of dielectric layers 116A-C. The metallization patterns 118A-C may include conductive lines, conductive vias, conductive pads, or other conductive features, and may be considered redistribution layers or interconnects in some cases. The second redistribution structure 120 described herein is an example, and may have a different numbers, arrangements, or configurations of dielectric layers or metallization patterns in other embodiments. For example, if fewer dielectric layers and metallization patterns are to be formed, some steps and processes discussed below may be omitted. If more dielectric layers and metallization patterns are to be formed, some steps and processes discussed below may be repeated.

The dielectric layers 116A-C of the second redistribution structure 120 may be formed of materials similar to those described for the dielectric layers 110A-D of the first redistribution structure 114. For example, in some embodiments, the dielectric layers 116A-C are formed of a polymer, which may be a photo-sensitive material such as PBO, polyimide, BCB, or the like, that may be patterned using a lithography mask. In other embodiments, the dielectric layers 116A-C may be formed of different materials than the dielectric layers 110A-C of the first redistribution structure 114. The dielectric layers 116A-C may be formed by any acceptable deposition process, such as spin coating, CVD, laminating, the like, or a combination thereof. In some embodiments, each dielectric layer 116A-C may be formed having a thickness T2 that is in the range of about 5 μm to about 10 μm, though other thicknesses are possible. The dielectric layers 116A-C may have similar thicknesses or different thicknesses. In some embodiments, each dielectric layer of the second redistribution structure 120 has a thickness (e.g., thickness T2) that is less than a thickness (e.g., thickness T1) of each dielectric layer of the first redistribution structure 114.

In FIG. 11, a dielectric layer 116A is deposited over the first redistribution structure 114, in accordance with some embodiments. For example, the dielectric layer 116A in FIG. 11 is deposited over the dielectric layer 110D and the metallization pattern 112D, which are the top-most dielectric layer and the top-most metallization layer of the first redistribution structure 114. As described previously, the dielectric layer 116A may have a thickness T2 that is less than that of the underlying dielectric layer 110D.

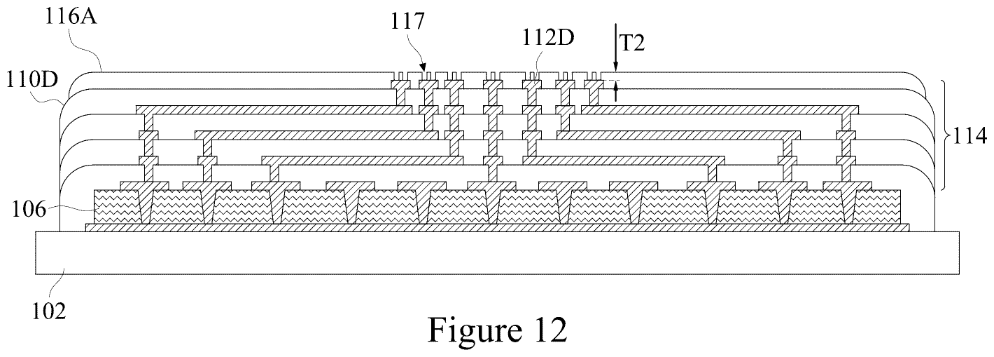

In FIG. 12, the dielectric layer 116A is patterned to form openings 117 exposing portions of the metallization pattern 112D. The dielectric layer 116A may be patterned using an acceptable photolithographic process. For example, in embodiments for which the dielectric layer 116A is a photo-sensitive material, the dielectric layer 116A may be exposed to light using a lithography mask. The dielectric layer 116A may then be developed after the exposure to form the openings 117. In other embodiments, a photoresist may be formed and patterned over the dielectric layer 116A, and then the dielectric layer 116A may be etched using the patterned photoresist as an etching mask. In some embodiments, the openings 117 may have a width in the range of about 5 μm to about 10 μm, though other widths are possible. In some embodiments, the openings 117 have a smaller width and/or a smaller pitch than the openings 111 (see FIG. 6).

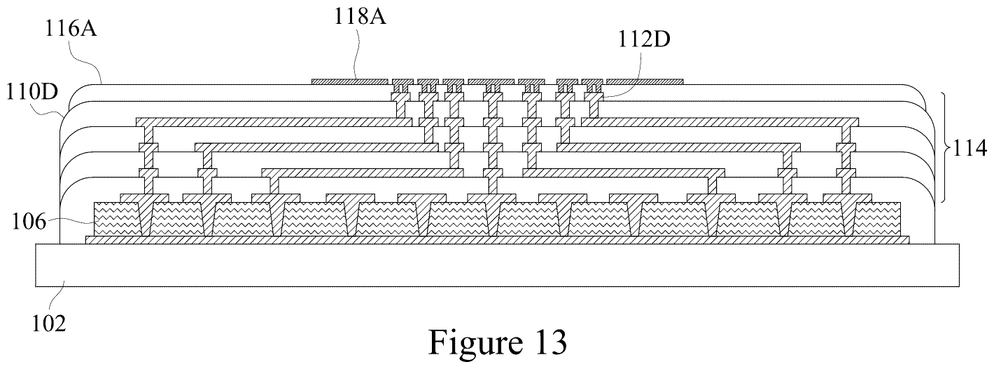

In FIG. 13, a metallization pattern 118A is formed on the dielectric layer 116A. The metallization pattern 118A comprises conductive lines that extend along the top surface of the dielectric layer 116A and conductive vias that extend through the openings 117 in the dielectric layer 116A to physically and electrically contact the metallization pattern 112D. The metallization pattern 118A may be formed using techniques similar to those described previously for forming the metallization pattern 112A. For example, a seed layer may first be formed over the dielectric layer 116A and within the openings 117. In some embodiments, the seed layer is similar to the seed layer 104 or other seed layers described herein. For example, the seed layer may comprise a metal layer formed using PVD or the like. A photoresist (not shown) is then formed and patterned on the seed layer, with the pattern of the photoresist corresponding to the metallization pattern 118A. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed using, for example, an ashing process. Once the photoresist is removed, exposed portions of the seed layer are removed using, for example, an acceptable wet etching process or dry etching process. The remaining portions of the seed layer and conductive material form the metallization pattern 118A.

In some embodiments, the conductive line portions of the metallization pattern 118A have a thickness over the dielectric layer 116A that is in the range of about 1 μm to about 10 μm, though other thicknesses are possible. The other metallization patterns 118B-C of the second redistribution structure 120 may have conductive line thicknesses that are similar to or different from the conductive line thickness of the metallization pattern 118A. In some embodiments, each metallization pattern of the second redistribution structure 120 has a thickness that is less than a thickness of each metallization pattern of the first redistribution structure 114. In some embodiments, each metallization pattern of the second redistribution structure 120 has a pitch that is less than a pitch of each metallization pattern of the first redistribution structure 114.

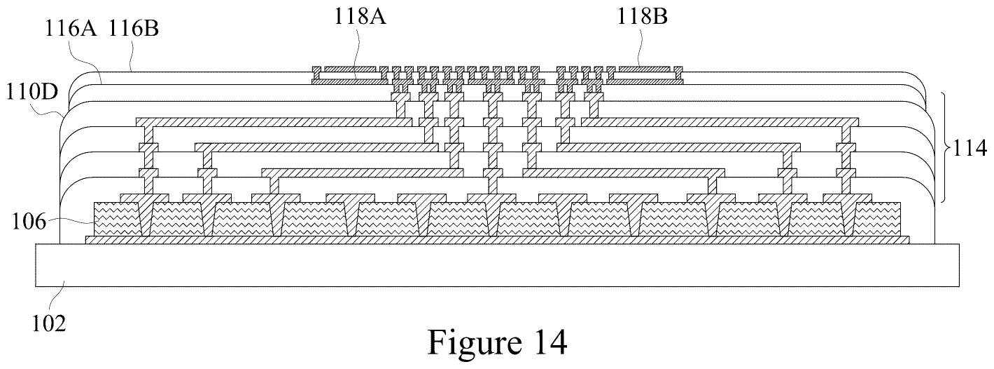

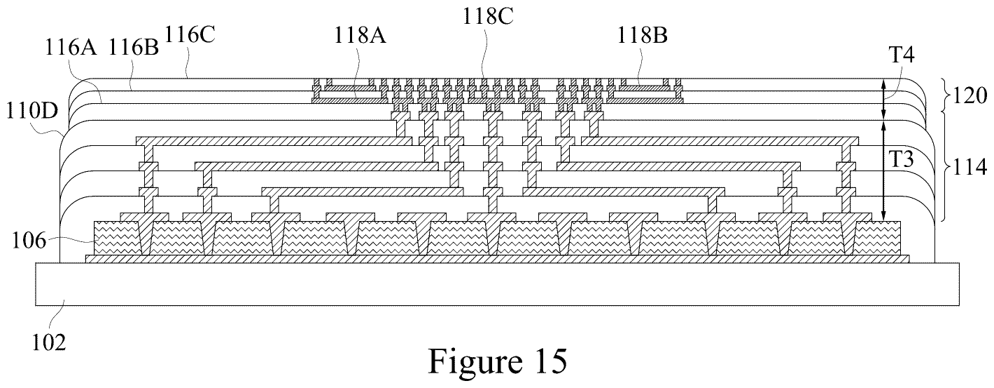

If more dielectric layers and metallization patterns are to be formed, steps and processes discussed above may be repeated. Referring to FIGS. 14-15, additional metallization patterns 118B-C may be formed using techniques similar to that of the metallization pattern 118A. For example, in FIG. 14, a dielectric layer 116B is formed over the dielectric layer 116A and the metallization pattern 118A. A metallization pattern 118B is formed comprising conductive line portions on the dielectric layer 116B, and conductive via portions extending through the dielectric layer 116B to physically and electrically contact the metallization pattern 118A. For example, the metallization pattern 118B may be formed by forming the seed layer and conductive material of the metallization pattern 118B over a surface of the underlying dielectric layer 116B and in openings of the underlying dielectric layer 116B, thereby interconnecting and electrically coupling various conductive lines. The thickness and materials of the dielectric layer 116B and metallization pattern 118B may be similar to those described for the dielectric layer 116A and metallization pattern 118A, in some embodiments.

In FIG. 15, a dielectric layer 116C is formed over the dielectric layer 116B and the metallization pattern 118B. A metallization pattern 118C is formed comprising conductive via portions extending through the dielectric layer 116C to physically and electrically contact the metallization pattern 118B. In some embodiments, the metallization pattern 118C is also formed comprising conductive line portions on the dielectric layer 116C. The metallization pattern 118C may be formed by forming the seed layer and conductive material of the metallization pattern 118C in openings of the underlying dielectric layer 116B, thereby interconnecting and electrically coupling various conductive lines. The thickness and materials of the dielectric layer 116C and metallization pattern 118C may be similar to those described for the dielectric layer 116A and metallization pattern 118A, in some embodiments.

As described above, in some embodiments the dielectric layers of the first redistribution structure 114 are thicker than the dielectric layers of the second redistribution structure 120. Additionally, the metallization patterns of the first redistribution structure 114 has conductive features (e.g., conductive lines and conductive vias) that are larger (e.g., thicker or wider) than the conductive features of the metallization patterns of the second redistribution structure 120. In some embodiments, a total thickness T3 of the first redistribution structure 114 may be larger than a total thickness T4 of the second redistribution structure 120. In other embodiments, the first redistribution structure 114 may have a total thickness T3 that is less than or about the same as a total thickness T4 of the second redistribution structure 120. In some embodiments, a total thickness T3 of the first redistribution structure 114 is in the range of about 100 μm to about 350 μm, and a total thickness T4 of the second redistribution structure 120 is in the range of about 15 μm to about 70 μm, though other thicknesses are possible. Forming a “thin” second redistribution structure 120 over and electrically coupled to a “thick” first redistribution structure 114 as described herein can allow for efficient fan-out routing within a package. In some cases, the first redistribution structure 114 and the second redistribution structure 120 together may be considered a “redistribution substrate” or a “routing structure” that is formed on the first composite layer 106.

Forming redistribution structures 114/120 on the first composite layer 106 as described herein can allow for improved yield, improved process throughput, and/or a thinner package. For example, forming the redistribution structures 114/120 using photolithographic techniques to pattern dielectric layers formed of polymer can result in better yield and faster processing than using other techniques, such as using laser drilling on layers of Ajinomoto build-up film (ABF), organic core, or the like. Additionally, in some cases, redistribution structures 114/120 using polymer layers can be formed having fewer and/or thinner layers than redistribution structures formed from layers of ABF or other composite materials. In this manner, the overall thickness of a package may be reduced. Further, by forming the redistribution structures 114/120 on the first composite layer 106, a package may have improved structural stability, improved thermal characteristics, and improved operation.

In FIG. 16, conductive connectors 122 are formed over the second redistribution structure 120, in accordance with some embodiments. The conductive connectors 122 may physically and electrically contact to the top-most metallization pattern of the second redistribution structure 120, such as the metallization pattern 118C of the second redistribution structure 120 shown in FIG. 16. The conductive connectors 122 may comprise ball grid array (BGA) connectors, solder balls, metal pillars, conductive pads, controlled collapse chip connection (C4) bumps, micro bumps, electroless nickel-electroless palladium-immersion gold technique (ENEPIG) formed bumps, under-bump metallizations (UBMs), or the like. The conductive connectors 122 may include a conductive material such as solder, copper, aluminum, gold, nickel, silver, palladium, tin, the like, or a combination thereof. In some embodiments, the conductive connectors 122 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 122 comprise metal pillars (such as copper pillars) formed by a sputtering, printing, electroplating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

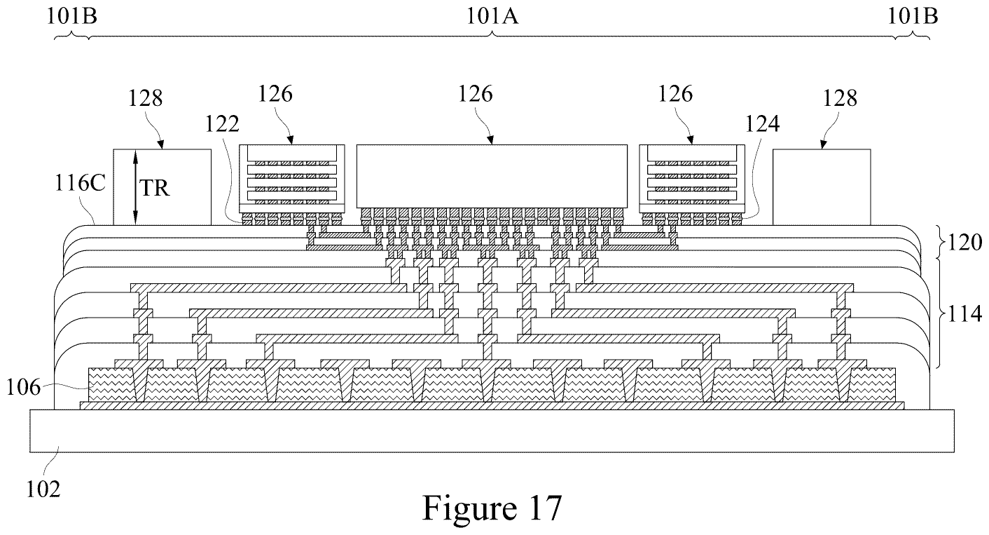

In FIG. 17, one or more integrated circuit dies 126 are attached to the second redistribution structure 120, in accordance with some embodiments. The integrated circuit dies 126 may include a logic die (e.g., central processing unit (CPU), graphics processing unit (GPU), system-on-a-chip (SoC), application processor (AP), microcontroller, application-specific integrated circuit (ASIC) die, etc.), a memory die (e.g., dynamic random access memory (DRAM) die, static random access memory (SRAM) die, hybrid memory cube (HMC) module, high bandwidth memory (HBM) module, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. Multiple integrated circuit dies 126 may include similar types of dies and/or different types of dies. The integrated circuit dies 126 may have different sizes (e.g., different heights and/or surface areas), or may have the same size (e.g., same heights and/or surface areas).

In some embodiments, the integrated circuit dies 126 are attached to the second redistribution structure 120 using solder regions, which may be formed on the conductive connectors 122 and/or on conductive connectors of the integrated circuit dies 126. The integrated circuit dies 126 may be placed on the second redistribution structure 120 using, e.g., a pick-and-place tool. After placing the integrated circuit dies 126 on the second redistribution structure 120, the solder regions are in physical contact with respective conductive connectors 122 of the second redistribution structure 120 and respective conductive connectors of the integrated circuit dies 126. After placing the integrated circuit dies 126 on the second redistribution structure 120, a reflow process in performed on the solder regions to melt and merge the solder regions into solder joints 124. The solder joints 124 electrically and mechanically couple the integrated circuit dies 126 to the second redistribution structure 120. In some embodiments, an optional underfill (not shown) may be formed between the integrated circuit dies 126 and the second redistribution structure 120. As shown in FIG. 17, in some embodiments, the integrated circuit dies 126 may be attached directly to the second redistribution structure 120 without an interposer or the like. In this manner, the redistribution structures 114/120 may take the place of an interposer, in some cases. In other embodiments, an interposer is disposed between the integrated circuit dies 126 and the second redistribution structure 120.

Still referring to FIG. 17, a support ring 128 is attached to the second redistribution structure 120, in accordance with some embodiments. The support ring 128 may be attached, for example, to provide mechanical support to the package and to reduce warpage. In some embodiments, the support ring 128 may encircle the integrated circuit dies 126. The support ring 128 may be formed of a rigid material, such as a metal, a semiconductor, a ceramic, or another material. In some embodiments, the support ring 128 may be attached to the top-most dielectric layer (e.g., dielectric layer 116C) of the second redistribution structure 120 using an adhesive film or the like (not shown). In some embodiments, the support ring 128 may have a thickness TR that is in the range of about 500 μm to about 700 μm, though other thicknesses are possible. The thickness TR of the support ring 128 may be greater than, about the same as, or less than a thickness of an integrated circuit die 126.

In FIG. 18, an encapsulant 130 is formed over the structure and the edge regions 101B are optionally trimmed, in accordance with some embodiments. The encapsulant 130 may be formed over and around the integrated circuit dies 126 and support ring 128, and may be formed underneath the integrated circuit dies 126 in some cases. In this manner, after formation, the encapsulant 130 encapsulates the integrated circuit dies 126 and the support ring 128. The encapsulant 130 may be a molding compound, epoxy, or the like. The encapsulant 130 may be applied by compression molding, transfer molding, or the like, and may be formed over the carrier substrate 102 such that the integrated circuit dies 126 and the support ring 128 are buried or covered. The encapsulant 130 may be applied in liquid or semi-liquid form and then subsequently cured.

In some embodiments, a planarization process may be performed after forming the encapsulant 130. The planarization process may include a chemical mechanical polish (CMP) process, a grinding process, or the like. The planarization process may remove encapsulant 130 from over the integrated circuit dies 126 and the support ring 128. In some embodiments, the planarization process may expose the support ring 128 and/or one or more of the integrated circuit dies 126. In other embodiments, the support ring 128 and/or one or more of the integrated circuit dies 126 may remain covered by the encapsulant 130, as shown in FIG. 18. After performing the planarization process, top surfaces of the encapsulant 130, the support ring 128, and/or one or more of the integrated circuit dies 126 may be level.

Further in FIG. 18, the edge regions 101B may optionally be trimmed, in accordance with some embodiments. The trimming process may partially or fully remove material within the edge regions 101B. The trimming process may include a mechanical sawing process, a laser sawing process, an etching process, the like, or a combination thereof. In some embodiments, after performing the trimming process, sidewall surfaces of the encapsulant 130, the first redistribution structure 114, the second redistribution structure 120, and/or the first composite layer 106 may be coplanar or coterminous.

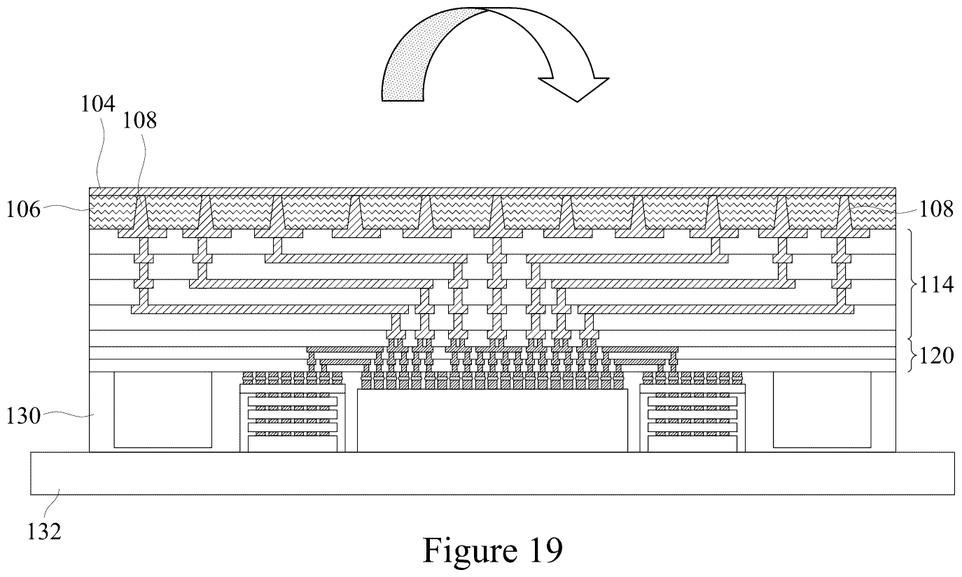

In FIG. 19, the package component of FIG. 18 is de-bonded from the carrier substrate 102, flipped upside-down, and bonded to another carrier substrate 132, in accordance with some embodiments. The carrier substrate 132 may be similar to the carrier substrate 102, in some cases. The package component may be attached to the carrier substrate 132 using an adhesive, a release layer, or the like (not shown).

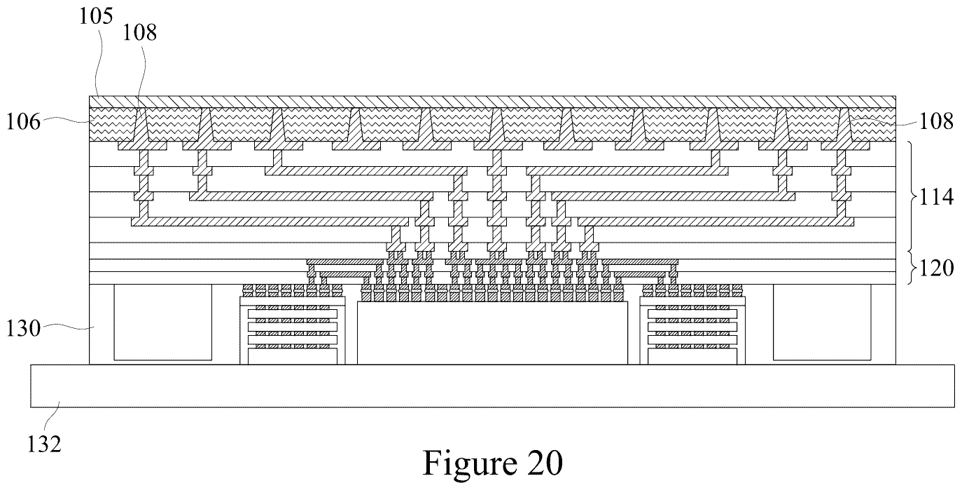

In FIG. 20, a metal layer 105 is formed on the seed layer 104, in accordance with some embodiments. The metal layer 105 may be formed, for example, using a plating process (e.g., electroplating, electroless plating, or the like) to deposit metal material(s) on the seed layer 104. The deposited metal material(s) and the seed layer 104 together form the metal layer 105, which physically contacts the first composite layer 106 and conductive via portions of the metallization pattern 108. The metal layer 105 may comprise one or more metals such as copper, titanium, tungsten, aluminum, or the like. In some embodiments, the metal layer 105 has a thickness in the range of about 20 μm to about 40 μm, though other thicknesses are possible. In some embodiments, the thickness of the metal layer 105 is greater than a thickness of the conductive line portions (e.g., the metallization layers) of the first redistribution structure 114 and/or the second redistribution structure 120.

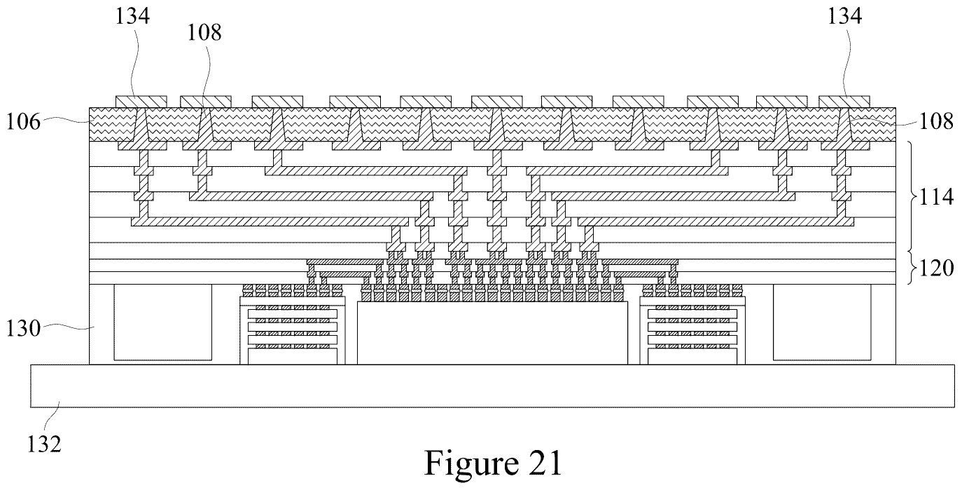

In FIG. 21, the metal layer 105 is patterned to form conductive elements 134 on the composite layer 106, in accordance with some embodiments. The conductive elements 134 may comprise, for example, conductive lines, conductive pads, or the like. The conductive elements 134 may physically and electrically contact to the conductive via portions of the metallization pattern 108. In some embodiments, the conductive elements 134 are thicker than the conductive line portions of the first redistribution structure 114 and/or the second redistribution structure 120. Forming relatively thicker conductive elements 134 in this manner can allow for efficient fan-out routing within a package. In some cases, the conductive elements 134 may be considered a metallization pattern.

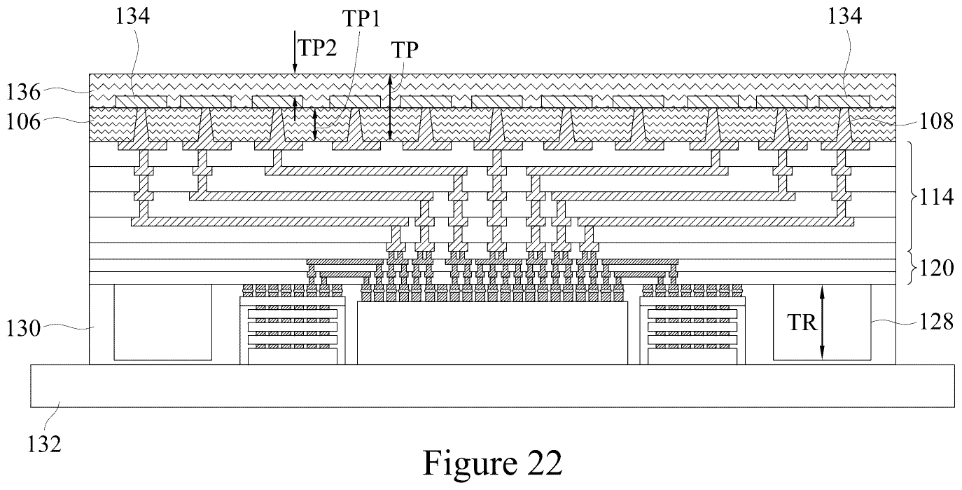

In FIG. 22, a second composite layer 136 is formed over conductive elements 134 and the first composite layer 106, in accordance with some embodiments. The second composite layer 136 may be formed of one or more layers of composite material(s), which may be similar to those described previously for the first composite layer 106. For example, the second composite layer 136 may be formed of prepreg or the like. In some embodiments, the second composite layer 136 may be a different material than the first composite layer 106, such as a prepreg having different characteristics. Other materials or combinations of materials are possible. In some cases, forming an insulating layer from a composite material such as prepreg can allow for packages to be formed having improved structural strength and a smaller overall thickness. In some embodiments, the material of the second composite layer 136 may be chosen to have a CTE similar to that of other features in the package, such as the integrated circuit dies 126, the first composite layer 106, the support ring 128, or the like. In some cases, the materials of the first composite layer 106 and the second composite layer 136 may be chosen to have a combined CTE that appropriately matches the CTE of the support ring 128. In this manner, a package may have improved thermal performance. In some cases, the first composite layer 106 and the second composite layer 136 together may be considered a “composite layer stack” or a “composite interconnect structure.”

In some embodiments, the second composite layer 136 may have a thickness TP2 that is in the range of about 100 μm to about 300 μm, though other thicknesses are possible. The second composite layer 136 may have a thickness TP2 that is greater than, about the same as, or less than a thickness TP1 of the first composite layer 106. In some embodiments, the first composite layer 106 and the second composite layer 136 may have a combined thickness TP that is in the range of about 500 μm to about 700 μm. In some embodiments, the total thickness TP of the composite layers 106/136 may be greater than the thickness T4 of the second redistribution structure 120. In some embodiments, the total thickness TP of the composite layers 106/136 may be about the same as a thickness TR of the support ring 128. In this manner, the structural and thermal performance of the package may be improved. Other thicknesses TP1, TP2, or TP or relative thicknesses thereof are possible.

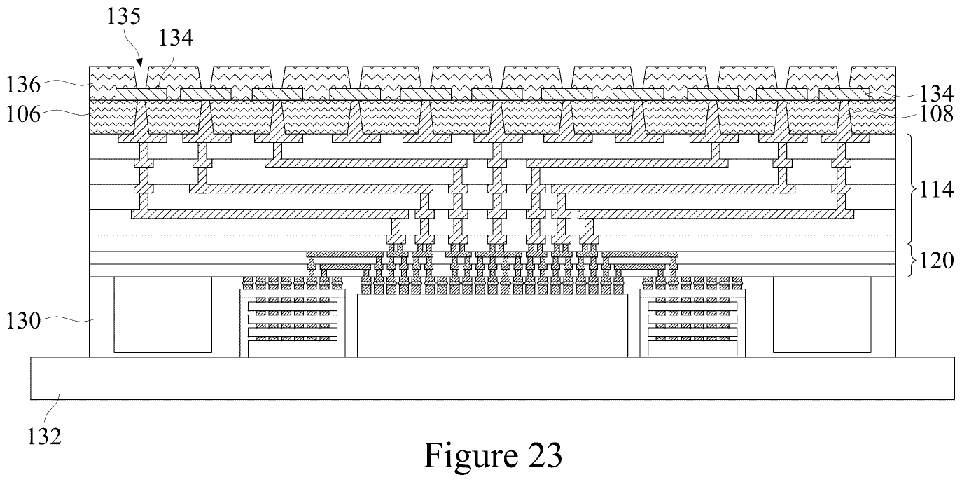

In FIG. 23, openings 135 are formed in the second composite layer 136, in accordance with some embodiments. The openings 135 may extend through the second composite layer 136 to expose portions of the conductive elements 134. The openings 135 may be formed using a technique similar to those described for the openings 107 (see FIG. 3). For example, the openings 135 may be formed using a mechanical drilling process, a laser drilling process, a photolithographic masking and etching process, or another suitable process. In some embodiments, each opening 135 may have a width in the range of about 100 μm to about 300 μm, though other widths are possible.

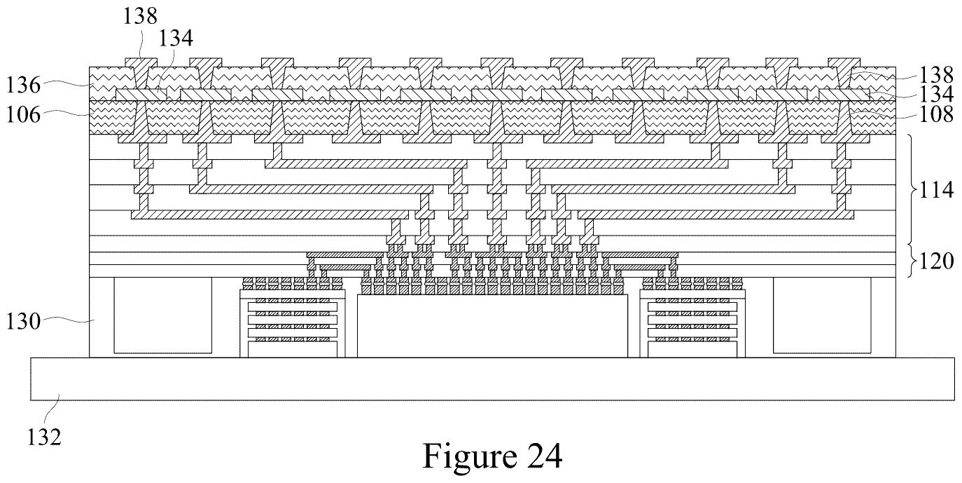

In FIG. 24, conductive material is deposited to form a metallization pattern 138, in accordance with some embodiments. The metallization pattern 138 includes conductive via portions that extend through the second composite layer 136 and physically and electrically contact the underlying conductive elements 134. As shown in FIG. 24, the metallization pattern 138 may also include conductive element portions that extend along the top surface of the second composite layer 136, such as conductive lines, conductive pads, or the like. In some embodiments, the conductive element portions of the metallization pattern 138 on the top surface of the second composite layer 136 may have a thickness in the range of about 100 μm to about 300 μm, though other thicknesses are possible. In some cases, the conductive elements 134, the metallization pattern 138, and the second composite layer 136 together may be considered an “interconnect layer.”

The metallization pattern 138 may be formed using techniques similar to those described for the metallization pattern 108. For example, a seed layer may be formed over the second composite layer 136 and into the openings 135, and a patterned photoresist may then be formed over the seed layer. A conductive material may be deposited on exposed portions of the seed layer. The conductive material may be similar to those described previously for the metallization pattern 108. The photoresist and underlying seed layer may then be removed using suitable processes, with the remaining portions of the seed layer and conductive material forming the metallization pattern 138. Other formation techniques are possible.

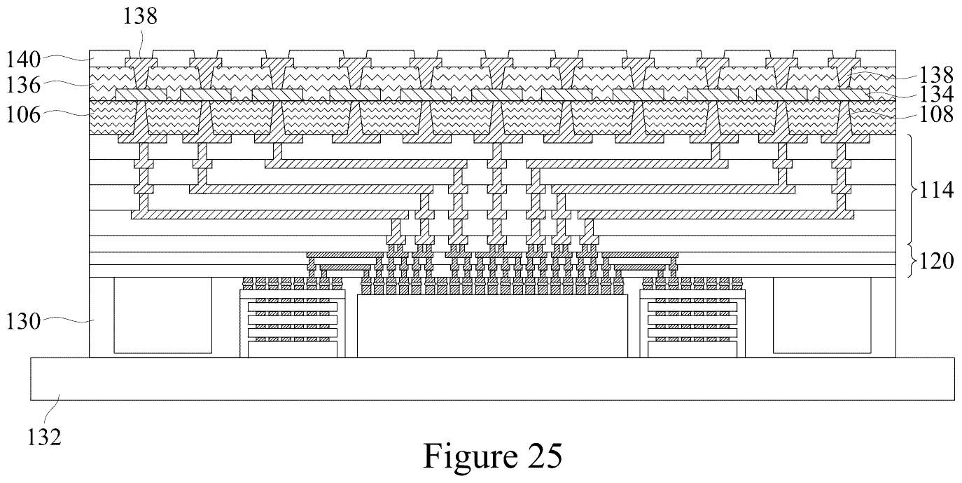

In FIG. 25, a solder resist layer 140 is formed over the second composite layer 136 and the metallization pattern 138, in accordance with some embodiments. The solder resist layer 140 may comprise a suitable insulating material, such as a dielectric material, a polymer material, or the like, and may be formed using any suitable deposition technique. In some embodiments, the solder resist layer 140 is patterned to form one or more openings in the solder resist layer 140 that expose portions of the metallization pattern 138. The patterning process may comprise suitable photolithography and etching techniques. The etching techniques may include a dry etching process or a wet etching process, and may be anisotropic.

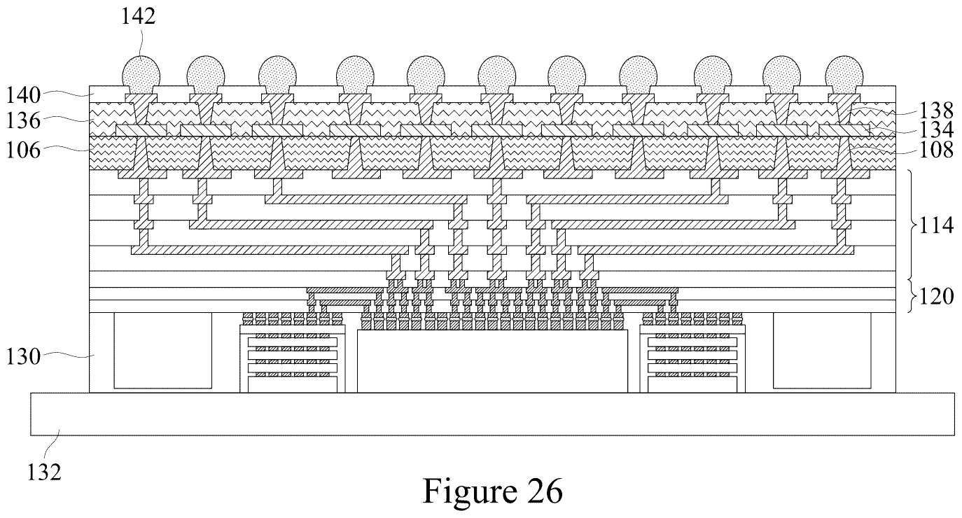

In FIG. 26, conductive connectors 142 are formed, in accordance with some embodiments. The conductive connectors 142 extend through the openings in the solder resist layer 140 to physically and electrically contact the exposed portions of the metallization pattern 138. The conductive connectors 142 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some cases, the conductive connectors 142 may be formed using similar materials and methods as the conductive connectors 122 described above with reference to FIG. 17.

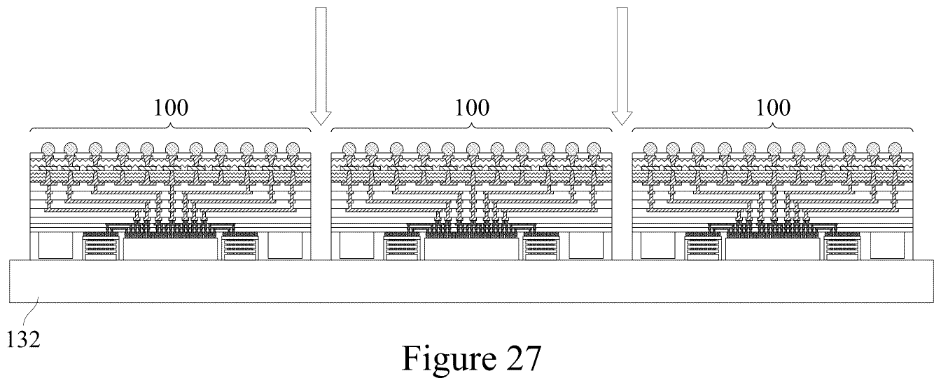

In FIG. 27, a singulation process is performed to separate the structure into individual integrated circuit packages 100, in accordance with some embodiments. The singulation process may include mechanical sawing, laser sawing, etching, dicing, a combination thereof, or the like. In some cases, the techniques described herein allow for the formation of integrated circuit packages 100 using only one singulation process. In other words, all sidewall layers of the integrated circuit packages 100 are sawed through in the same process, avoiding the need for multiple sawing processes to be performed during the formation of integrated circuit packages 100. In this manner, a package may be formed using fewer processing steps, which can reduce cost and improve throughput.

FIG. 28 illustrates a singulated integrated circuit package 100, in accordance with some embodiments. Due to the singulation process as described above, the integrated circuit package 100 has planar sidewalls. For example, as shown in FIG. 28, sidewall surfaces of the encapsulant 130, the first composite layer 106, the second composite layer 136, the first redistribution structure 114, the second redistribution structure 120, and/or the solder resist layer 140 may be coplanar (e.g., coterminous).

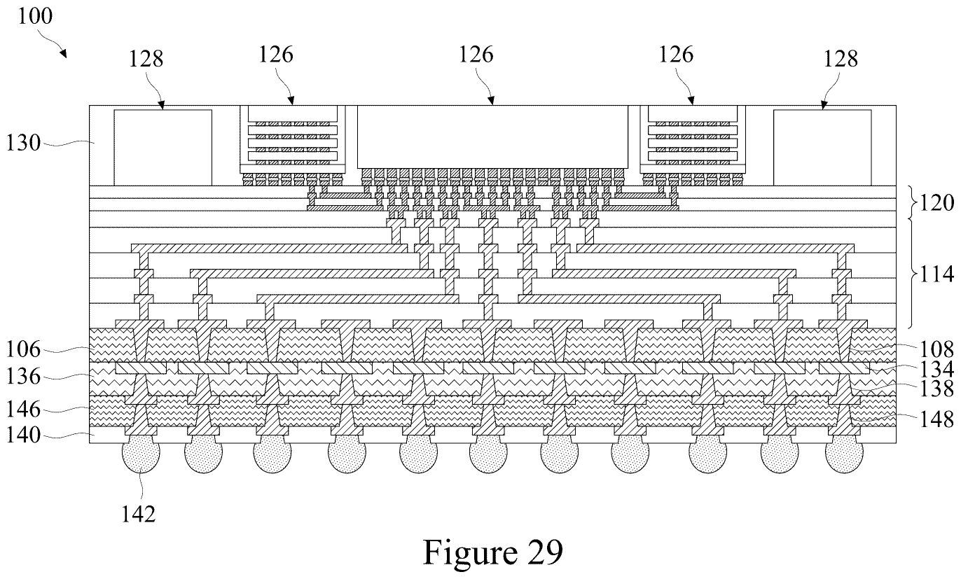

In other embodiments, the composite interconnect structure of an integrated circuit package 100 may comprise another number of composite layers and associated metallization patterns. As an example, FIG. 29 illustrates an integrated circuit package 100 that is similar to the integrated circuit package 100 of FIG. 28, except that a third composite layer 146 is formed on the second composite layer 136. Additionally, a metallization pattern 148 is formed on the third composite layer 146. The metallization pattern 148 may include conductive via portions that extend through the third composite layer 146 and physically and electrically contact the underlying metallization pattern 138. As shown in FIG. 29, the metallization pattern 148 may also include conductive element portions that extend along the top surface of the third composite layer 146, such as conductive lines, conductive pads, or the like. The third composite layer 146 may be formed using materials and techniques similar to those described previously for the first composite layer 106 and/or the second composite layer 136. The composite layers 106/136/146 may be formed of similar materials or different materials. The metallization pattern 148 may be formed using materials and techniques similar to those described previously for the metallization pattern 108 and/or the metallization pattern 138. In some cases, the metallization pattern 148 and the third composite layer 146 together may be considered an “interconnect layer.” The process steps described for the composite layers 136/146 and metallization patterns 138/148 may be repeated to form any desired number of composite layers and metallization patterns in an integrated circuit package 100. The conductive connectors 142 may be formed on the metallization pattern 148. In some cases, forming additional composite layers and metallization patterns can provide improved structural stability, improved thermal performance, and additional electrical routing.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. Forming routing over a composite layer using polymer layers instead of, for example, ABF layers can improve yield, increase through-put, increase routing density, and reduce package thickness. For example, using photolithographic techniques rather than laser drilling can avoid drilling particulates that reduce yield and can form multiple openings simultaneously rather than sequentially, which can increase process through-put. Additionally, using polymer layers instead of ABF layers or the like can reduce the overall number of layers used for routing, which can reduce thickness, processing time, and cost. Forming a second redistribution structure having thinner dielectric layers and smaller linewidths over a first redistribution structure having thicker dielectric layers and larger linewidths can provide efficient fan-out routing for a package. The techniques described herein also allow for a single sawing or singulation process to be performed, which can reduce processing time and cost, and improve through-put. Additionally, forming multiple composite layers can improve package strength and allow for better CTE matching, which can improve thermal performance of the package.

In accordance with an embodiment of the present disclosure, a method includes forming first conductive elements on and extending through a first composite layer; forming a first polymer layer on the first composite layer; forming a first metallization pattern extending through the first polymer layer; forming a second polymer layer over the first polymer layer, wherein the second polymer layer is thinner than the first polymer layer; forming a second metallization pattern on and extending through the second polymer layer, wherein the second metallization pattern is thinner than the first metallization pattern; forming a second composite layer on the first composite layer; and forming second conductive elements extending through the second composite layer. In an embodiment, forming the first metallization pattern includes patterning the first polymer layer using a lithography mask to expose a first conductive element and depositing a conductive material on the first polymer layer and on the exposed first conductive element. In an embodiment, the method includes connecting integrated circuit dies to the second metallization pattern. In an embodiment, the first composite layer includes a layer of prepreg material. In an embodiment, the first polymer layer physically contacts the first composite layer. In an embodiment, the method includes, before forming the second composite layer, forming third conductive elements on the first composite layer and on the first conductive elements. In an embodiment, a thickness of the third conductive elements is greater than a thickness of the first metallization pattern. In an embodiment, the first polymer layer and the second polymer layer include different polymers.

In accordance with an embodiment of the present disclosure, a method includes forming a first interconnect layer on a first carrier substrate, wherein the first interconnect layer includes a first composite material; forming a first redistribution structure on the first interconnect layer, wherein forming the first redistribution structure includes depositing a first dielectric layer; patterning the first dielectric layer using a lithography mask; and depositing a first conductive material on the first dielectric layer; forming a second redistribution structure on the first redistribution structure, wherein forming the second redistribution structure includes depositing a second dielectric layer; patterning the second dielectric layer using a lithography mask; and depositing a second conductive material on the second dielectric layer; and attaching an integrated circuit die to the second redistribution structure. In an embodiment, the first conductive material is deposited to a first thickness and the second conductive material is deposited to a second thickness that is less than the first thickness. In an embodiment, the first dielectric layer includes at least one of polybenzoxazole (PBO), polyimide, or benzocyclobutene (BCB). In an embodiment, the method includes attaching a supporting ring to the second redistribution structure. In an embodiment, the method includes forming a second interconnect layer on the first interconnect layer, wherein the second interconnect layer includes a second composite material, wherein the second interconnect layer is electrically connected to the first interconnect layer. In an embodiment, the method includes performing a sawing process, wherein after performing the sawing process, sidewall surfaces of the first interconnect layer, the first redistribution structure, the second redistribution structure are coplanar. In an embodiment, the method includes, before forming the first interconnect layer, depositing a seed layer on the first carrier substrate.

In accordance with an embodiment of the present disclosure, a package includes a first composite layer; a second composite layer on the first composite layer; conductive elements within the first composite layer and the second composite layer; a first redistribution structure on the second composite layer, wherein the first redistribution structure includes first polymer layers and first conductive lines; a second redistribution structure on the first redistribution structure, wherein the second redistribution structure includes second polymer layers and second conductive lines, wherein the second polymer layers are thinner than the first polymer layers, wherein the second conductive lines are thinner than the first conductive lines; and a semiconductor device attached to the second redistribution structure. In an embodiment, the package includes an encapsulant over the semiconductor device, wherein the encapsulant and the second redistribution structure have coplanar sidewalls. In an embodiment, the first composite layer, the second composite layer, the first redistribution structure, and the second redistribution structure have coplanar sidewalls. In an embodiment, a thickness of the first redistribution structure is greater than a thickness of the second redistribution structure. In an embodiment, a combined thickness of the first composite layer and the second composite layer is greater than a thickness of the second redistribution structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a first interconnect structure comprising a plurality of first conductive features in a stack of prepreg layers;
a second interconnect structure on the first interconnect structure, wherein the second interconnect structure comprises a plurality of second conductive features in a stack of first polymer layers;
a third interconnect structure on the second interconnect structure, wherein the third interconnect structure comprises a plurality of third conductive features in a stack of second polymer layers, wherein the second polymer layers are thinner than the first polymer layers;
a semiconductor device attached to the third interconnect structure; and
an encapsulant on the third interconnect structure and surrounding the semiconductor device.

2. The package of claim 1, wherein first polymer layers are a different polymer than the second polymer layers.

3. The package of claim 1, wherein the second interconnect structure physically contacts the first interconnect structure.

4. The package of claim 1, wherein sidewalls of the first interconnect structure, the second interconnect structure, the third interconnect structure, and the encapsulant have coplanar sidewalls.

5. The package of claim 1 further comprising a support ring attached to the third interconnect structure.

6. The package of claim 5, wherein the stack of prepreg layers and the support ring have a same thickness.

7. The package of claim 1, wherein a thickness of the second interconnect structure is greater than a thickness of the third interconnect structure.

8. The package of claim 1, wherein a thickness of the first interconnect structure is greater than a thickness of the second interconnect structure.

9. A structure comprising:
a first composite layer;
first conductive features extending through the first composite layer;
a second composite layer on the first composite layer;
second conductive features extending through the second composite layer;
a first polymer layer over the second composite layer;
third conductive features extending through the first polymer layer, wherein the third conductive features have a first pitch;
a second polymer layer over the first polymer layer;
fourth conductive features extending through the second polymer layer, wherein the fourth conductive features have a second pitch smaller than the first pitch; and
a semiconductor die connected to the fourth conductive features.

10. The structure of claim 9, wherein a thickness of a second conductive feature is greater than a thickness of a third conductive feature.

11. The structure of claim 9, wherein the first composite layer has a different composition than the second composite layer.

12. The structure of claim 9, wherein the second composite layer is a prepreg layer.

13. The structure of claim 9, wherein the second composite layer has a thickness in the range of 100 μm to 300 μm.

14. The structure of claim 9, wherein the semiconductor die is connected to the fourth conductive features by solder balls.

15. The structure of claim 9, wherein the first polymer layer has a thickness in the range of 10 μm to 60 μm.

16. The structure of claim 9, wherein the second polymer layer has a thickness in the range of 5 μm to 10 μm.

17. A method comprising:
forming a first metallization pattern on a first composite layer;
depositing a first photo-sensitive polymer material over the first composite layer;
forming a second metallization pattern on the first photo-sensitive polymer material;
depositing a second photo-sensitive polymer material over the first photo-sensitive polymer material;
forming a third metallization pattern on the second photo-sensitive polymer material, wherein the second metallization pattern is thicker than the third metallization pattern;
after forming the third metallization pattern, forming a fourth metallization pattern on the first composite layer;
forming a second composite layer on the first composite layer; and
forming a fifth metallization pattern on the second composite layer.

18. The method of claim 17, wherein the first metallization pattern is thicker than the third metallization pattern.

19. The method of claim 17 further comprising, before forming the second composite layer, sawing through the first composite layer, the first photo-sensitive polymer material, and the second photo-sensitive polymer material.

20. The method of claim 17 further comprising attaching a plurality of semiconductor devices to the third metallization pattern.
